(19) United States
(12) Patent Application Publication
(10) Pub. No.: US 2013/0240026 A1
(43) Pub. Date: Sep. 19, 2013

(54) PHOTOVOLTAIC SEMICONDUCTIVE MATERIALS

(71) Applicants: Harry A. Atwater, S. Pasadena, CA (US); Naomi Coronel, Pasadena, CA (US); Lise Lahourcade, Lausanne (CH)

(72) Inventors: Harry A. Atwater, S. Pasadena, CA (US); Naomi Coronel, Pasadena, CA (US); Lise Lahourcade, Lausanne (CH)

(73) Assignee: THE CALIFORNIA INSTITUTE OF TECHNOLOGY, Pasadena, CA (US)

(21) Appl. No.: 13/602,115

(22) Filed: Sep. 1, 2012

Related U.S. Application Data
(60) Provisional application No. 61/530,893, filed on Sep. 2, 2011.
(60) Provisional application No. 61/599,055, filed on Feb. 15, 2012.

(51) Int. Cl. H01L 31/032; H01L 31/18

(52) U.S. Cl. CPC H01L 31/032; H01L 31/18
USPC 136/255; 438/94; 136/261

(57) ABSTRACT

The disclosure provides semiconductive material derived from group IV elements that are useful for photovoltaic applications.

### CROSS REFERENCE TO RELATED APPLICATIONS

This application claims priority under 35 U.S.C. §119 from Provisional Application Ser. Nos. 61/530,893, filed Sep. 2, 2011, and 61/599,055, filed Feb. 15, 2012, the disclosures of which are incorporated herein by reference.

### STATEMENT AS TO FEDERALLY SPONSORED RESEARCH

This invention was made with government support under grant no. DE-FG36-08GO18006 (T-105257) awarded by the Department of Energy. The government has certain rights in the invention.

### TECHNICAL FIELD

The disclosure provides semiconductive material useful for photovoltaic applications.

### BACKGROUND

Terawatt-scale energy demands motivate the investigation of new visible-range direct band gap semiconductor materials that are abundant and low-cost.

### SUMMARY

The disclosure provides a semiconductive device having a substrate layer; and at least one absorber layer comprising Zn-IV-N₂ or Zn-IV₁-IV₂-N₂, where IV=Sn, Ge, or Si deposited on the substrate layer and wherein IV₁ and IV₂ are not the same. The semiconductive device finds use in optoelectronics and photovoltaic applications. In one embodiment, the substrate is selected from the group consisting of silicon, silicon carbide, sapphire, aluminum nitride and Ga—N. In another embodiment, the substrate is selected from the group consisting of silicon, silicon carbide, sapphire and aluminum nitride and wherein a layer of Ga—N is layered on the substrate. In further embodiment, the device further comprises a nucleation layer between the substrate and the Ga—N buffer layer. In still yet other embodiments of any of the foregoing, the absorber layer comprises ZnSnN₂. In yet another embodiment, the device comprises a window layer of ZnSiN₂. In any of the foregoing embodiments, the absorber layer comprises a ZnSnN₂/ZnGeN₂ having a type II heterojunction. In yet another embodiment, the absorber layer comprises gradual band gap absorber layers made of ZnₓSn_{y}Ge_{1-x-y},N₂. In one embodiment, the absorber layer is an ZnSnN₂ layer and has a wurtzite-derived Pna2₁ orthorhombic structure. In yet another embodiment, the absorber layer comprises a characteristics selected from the group consisting of: (a) a band gap of about 1.4 eV at zero Kelvin; (b) an optical band gap of about 2.1 eV; and (c) electron concentrations of about 10²¹ cm⁻³.

The disclosure also provides a method of making a semiconductive ZnSnN₂ thin film, comprising RF-sputtering (i) ZnₓSn₁₋ₓ, or (ii) Zn and Sn with an Ar/N₂ plasma on a substrate.

The disclosure also provides a method of making ZnSnₓGe₁₋ₓN₂ alloy thin films with 0<x<1 by reactive RF sputtering, chemical vapor deposition, or molecular beam epitaxy on a substrate.

In one embodiment of either of the foregoing methods the substrate is selected from the group consisting of silicon, silicon carbide, sapphire, aluminum nitride and Ga—N. In another embodiment of either of the foregoing embodiments the substrate is selected from the group consisting of silicon, silicon carbide, sapphire and aluminum nitride and wherein a layer of Ga—N is layered on the substrate. In another embodiment, the substrate is removed after layering the absorber layer.

The disclosure also provides a semiconductive device made by any of the foregoing methods.

The details of one or more embodiments of the invention are set forth in the accompanying drawings and the description below. Other features, objects, and advantages of the invention will be apparent from the description and drawings, and from the claims.

### DESCRIPTION OF DRAWINGS

FIG. 1A-D shows calculated ZnSnN₂ crytallographic structure. (a) Comparison of the total energy per unit cell of the zinc-blende and wurtzite structures indicates that ZnSnN₂ should be more stable when crystallizing in the wurtzite-derived system. (b) Schematic of the Pna2₁ structure. c-plane metallic sublayer atomic arrangement of the wurtzite-derived ZnSnN₂ in (c) the 8-atom Pmc2₁ and (d) the 16-atom Pna2₁ (d) orthorhombic structures.

FIG. 2A-B shows calculated ZnSnN₂ electronic structure. (a) Band-structure and (b) electronic density of states of orthorhombic Pna2₁ ZnSnN₂, calculated using the HSE06 density functional: the semiconductor is expected to have a direct band gap of approximately 1.4 eV at zero Kelvin.

FIG. 3A-D shows ZnSnN₂ epitaxy on GaN(0001). (a) X-ray diffractograms of (001)-oriented layers deposited under the optimized conditions on both c-oriented sapphire and GaN. (b) The pole figure of a ZnSnN₂ layer grown epitaxially on top of GaN(0001) confirms the presence of the (001) orientation exclusively. (c) Schematic of the arrangement of the metallic atoms for both the layer and the template, in the c-plane (left).

Illustration of the epitaxial relationship between ZnSnN₂ and GaN, viewed along the GaN<1100> azimuth (right). (d) Cross-sectional HRTEM image of (001)-oriented ZnSnN₂ layer grown on top of GaN(0001) template.

FIG. 4A-C shows Burstein-Moss effect in ZnSnN₂. (a) Strong n-type doping of ZnSnN₂ leads to conduction band filling and the resulting Burstein-Moss effect: the effective band gap lies at higher energy than the fundamental band gap. (b) Calculated shift of the optical band gap with the electron doping concentration. (c) Typical spectroscopic ellipsometry measurement: the linear dependence of α² versus the photon energy is typical of a direct band gap semiconductor, with an absorption edge above 1.8 eV for the samples under consideration.

FIG. 5 shows optimization of ZnSnN₂ sputter deposition from a single Zn_{0.75}Sn_{0.25} target. The atomic composition of ZnSnN₂ is plotted for varying plasma power, working pressure, and deposition temperature. The oxygen concentration is decreased below the EDS detection limit for layers deposited under plasma powers higher than 130 W and a working pressure below 5 mTorr. Finally, oxygen-free layers become stoichiometric if deposited at 250±25° C., in order to compensate for the excess Zn in the target.

FIG. 6A-B shows XRD analysis of ZnSnN₂ crystallinity. (a) X-ray diffractograms of ZnSnN₂ layers deposited at different temperatures under the optimized plasma power and working pressure and with an Ar/N₂ ratio of 5/5. The main peak at 2θ˜32.3° is attributed to ZnSnN₂ (002) and is found only for layers close to the stoichiometry. (b) Under the best conditions, N₂ concentration of 66% in the plasma leads to the most crystalline (001)-oriented layers.

FIG. 7 shows Optimization of ZnSnN₂ co-sputter deposition from Zn and Sn elemental targets. X-ray diffractograms and atomic layer composition of ZnSnN₂ layers deposited by co-sputtering under the conditions shown and with a working pressure of 3 mTorr. Films close to stoichiometry exhibit the ZnSnN₂(002) peak at 20-32.3°. The best quality films were deposited with increased N concentration in the plasma and increased RF power on the Sn target. Error bars in the composition graph indicate the range of measured values for different locations on each sample.

FIG. 8A-C shows temperature-dependent XRD measurements to determine ZnSnN₂ thermal expansion. (a) X-ray diffraction spectra of ZnSnN₂ on GaN(0001) measured at various temperatures, which were used to determine (b) the evolution of the lattice parameters and (c) the thermal expansion coefficients, thereby defining a trend to extrapolate the zero Kelvin lattice parameters to 300 K.

FIG. 9 shows powder diffraction spectrum of ZnSnN₂. The sharp peaks come from the sapphire substrate, whereas the broader ones are attributed to the layer. Superimposed are the calculated structure factors, F*F, of Pna2₁ diffracting planes after extrapolation of the lattice parameters to 300 K.

FIG. 10 shows XRD analysis of the epitaxial relationship between ZnSnN₂ and GaN. Asymmetric reciprocal space map around the GaN(1124) reflection, showing ZnSnN₂(404) as well, which implies <100>_{ZnSnN}_{₂}∥<1120>_{GaN}.

FIG. 11A-C show diagrams of a device and layers of the disclosure.

FIG. 12 shows energy dispersive X-ray spectroscopy measurements for ZnSnₓGe₁₋ₓN₂ films with varying compositions.

FIG. 13 shows X-ray diffractograms for ZnSnₓGe₁₋ₓN₂ films with varying x, showing the shift in the (002) peak position with changing composition.

FIG. 14 shows squared absorption coefficient vs. photon energy for ZnSnₓGe₁₋ₓN₂ samples with varying x, showing an increasing optical band gap with decreasing x.

### DETAILED DESCRIPTION

As used herein and in the appended claims, the singular forms “a,” “and,” and “the” include plural referents unless the context clearly dictates otherwise. Thus, for example, reference to “a substrate” includes a plurality of such substrates and reference to “the layer” includes reference to one or more layers and equivalents thereof known to those skilled in the art, and so forth.

Unless defined otherwise, all technical and scientific terms used herein have the same meaning as commonly understood to one of ordinary skill in the art to which this disclosure belongs. Although any methods and reagents similar or equivalent to those described herein can be used in the practice of the disclosed methods and compositions, the exemplary methods and materials are now described.

All publications mentioned herein are incorporated herein by reference in full for the purpose of describing and disclosing the methodologies, which are described in the publications, which might be used in connection with the description herein. The publications discussed above and throughout the text are provided solely for their disclosure prior to the filing date of the present application. Nothing herein is to be construed as an admission that the inventors are not entitled to antedate such disclosure by virtue of prior disclosure.

For the past two decades, group III-nitride semiconductors (AlₓGa_{y}In_{1-x-y}N) have received considerable attention due to their favorable properties for applications in optoelectronic and electronic devices. Because of band gap tunability across the entire visible spectrum and continuously improving material quantum efficiency, InGaN-based alloys are of increasing interest for new efficient absorber layers in solar cells. In particular, with a band gap matching the AM 1.5 solar spectrum, an In_{0.4}Ga_{0.6}N absorber layer could reach a maximum theoretical detailed balance efficiency of around 33%. However, the large lattice mismatch between InN and GaN results in indium segregation and phase separation in high indium content layers, which makes it difficult to fabricate high-quality InGaN with more than 20% indium. Despite that difficulty, recent progress has been made in low indium content InGaN for solar energy conversion, although the low indium content limits the useful wavelengths to the green and blue spectral regions (<530 nm): today's record external quantum efficiency is 72% with an internal quantum efficiency of 97%, obtained for a solar cell with 12% indium in the active absorber layer. However, even with future improvements, the cost of indium, being a rather rare metal in the Earth's crust, makes it of potentially limited use for large-scale photovoltaic demands.

In this context, the disclosure describes compositions and method of making Zn-IV-N₂ semiconductors, where IV=Sn, Ge, or Si. In addition, the disclosure describes compositions and method of making Zn-IV₁-IV₂—N₂ (e.g., ZnSnₓGe₁₋ₓN₂) semiconductors wherein IV₁ and IV₂ are selected from the group consisting of Sn, Ge and Si, and wherein IV₁ and IV₂ are not the same elements. These materials exhibit properties that are similar, if not superior, to those of their well-known III-nitride counterparts, with the added benefit of being comprised of earth-abundant materials. Changing from one group-III element into a combination of group-II and -IV elements also widens the range of accessible properties. In particular, given studies for ZnGeN₂ and ZnSiN₂, the direct band gaps were expected to range from 0.35 eV to 6.01 eV for alloys in the series of ZnSnN₂, ZnGeN₂ and ZnSiN₂. For ZnSnN₂ a direct band gap of 2.02 eV was calculated using the quasiparticle self-consistent GW technique. Furthermore, a hybrid density functional calculation predicts a band gap of 1.42 eV and 2.87 eV for ZnSnN₂ and ZnGeN₂, respectively. These calculations also indicate a type II band alignment between ZnSnN₂ and ZnGeN₂, suggesting the possibility of photovoltaic heterojunction devices designed for direct charge separation at the ZnSnN₂/ZnGeN₂ interface. In light of these predictions, focus was placed on the fabrication of ZnSnN₂ and ZnSnₓGe₁₋ₓN₂, which have not been previously reported and which is essential to any future Zn-IV-N₂ photovoltaic device.

Referring to FIG. 11A-C, various layered semiconductive devices of the disclosure are depicted. Referring to FIG. 11A a two layer device is shown comprising a substrate (20) layered with a Zn(Sn,Ge)N₂ absorber layer (30). The substrate (20) can be any number of materials including, but not limited to sapphire (Al₂O₃), silicon, silicon carbide, aluminum nitride and GaN. Such substrates are commercially available. The absorber layer (30) can comprise ZnSnN₂, ZnGeN₂ or ZnSnₓGe₁₋ₓN₂. As described in more detail below, the absorber layer can be disposed on the substrate using an RF sputtering technique with a Ar/N₂ plasma. Referring to FIG. 11B a three layer semiconductive device is shown. The three layer device comprises a substrate (20a). Substrate layer 20a can be any number of materials including, but not limited to sapphire (Al₂O₃), silicon, silicon carbide, and aluminum nitride (note, in this embodiment GaN is not included as a substrate). A GaN layer (40) is disposed on substrate (20a). GaN layer (40) serves as an absorber layer-substrate and is layered with a Zn(Sn,Ge)N₂ absorber layer (30). The absorber layer (30) can comprise ZnSnN₂, ZnGeN₂ or ZnSnₓGe₁₋ₓN₂. As described in more detail below, the absorber layer can be disposed on the GaN layer (40) using an RF sputtering technique with a Ar/N₂ plasma. Referring to FIG. 11C a multilayer, multijunction device is shown. The three layer device comprises a substrate (20a). Substrate layer 20a can be any number of materials including, but not limited to sapphire (Al₂O₃), silicon, silicon carbide, and aluminum nitride (note, in this embodiment GaN is not included as a substrate). A GaN layer (40) is disposed on substrate (20a). GaN layer (40) serves as an absorber layer-substrate and is layered with absorber layers 30 and 50. Each absorber layer comprises a Zn(Sn,Ge)N₂ material. For example, absorber layer 30 can comprise ZnSnN₂ and absorber layer 50 can comprise ZnGeN₂ or vice versa. The absorber layer (30 and 50) can comprise ZnSnN₂, ZnGeN₂ or ZnSnₓGe₁₋ₓN₂. As described in more detail below, the absorber layer can be disposed on the GaN layer (40) using an RF sputtering technique with a Ar/N₂ plasma.

In one aspect, the disclosure demonstrates the synthesis of a single phase ZnSnN₂ thin film on c-plane sapphire and epitaxial ZnSnN₂(001) film on GaN(0001) substrates, thus providing a new class of zinc- and nitrogen-based semiconductors for visible frequency optoelectronics and photovoltaics. The ZnSnN₂ layers exhibit the wurtzite-derived Pna2₁ orthorhombic structure, in good agreement with ab initio calculations. The electronic structure calculations also indicate a direct band gap of approximately 1.4 eV at zero Kelvin, which is of high interest for a photovoltaic absorber.

Spectroscopic ellipsometry reveals an optical band gap of about 2.1 eV and Hall measurements indicate electron concentrations as high as ˜10²¹ cm⁻³. These values are consistent with heavy donor doping, where the fundamental band gap of ˜1.4 eV at zero Kelvin is altered by a strong Burstein-Moss effect resulting from conduction band filling.

In another aspect, the disclosure provides thin film growth of ZnSnₓGe₁₋ₓN₂ alloys by reactive RF co-sputtering from metal targets in a nitrogen-rich plasma, where x is varied by changing the RF power applied to the targets. The results show the thin film (002) peak position from X-ray diffraction linearly increases in 20 with increasing germanium content over a wide range of compositions, signifying that phase separation is not occurring and thus it is possible to access the entire range of band gaps between ZnSnN₂ and ZnGeN₂.

The disclosure provides methods of producing ZnSnN₂, ZnGeN₂ or ZnSnₓGe₁₋ₓN₂ layers. A first method includes RF sputtering of a single combination material comprising a combination of Zn and the Group IV element in a Ar/N₂ plasma. The second method includes the co-sputtering of each element individually in an Ar/N₂ plasma (e.g., Zn as one sputtering material and the Group IV element as the second sputtering material). For example, for production of ZnSnₓGe₁₋ₓN₂ for x=0 or 1, films were deposited by co-sputtering from zinc (99.99%) and germanium (99.999%) or zinc and tin (99.999%) elemental targets. For films with 0<x<1, Zn_{0.75}Sn_{0.25} pressed powder target was sputtered and a germanium elemental target was sputtered. The amount of N₂ in the plasma can be varied as desired. By modifying three parameters one can achieve the desired conditions for stoichiometric and crystalline films include target composition (sputtering vs. co-sputtering), plasma power (species partial pressure) and deposition temperature. The gas ratio and working pressure are additional fine tuning knobs during synthesis.

Sputtering is a term used to describe the mechanism in which atoms are dislodged from a surface of a target by collision with high-energy ions or particles. Examples of a sputtering method include an RF sputtering method in which a high-frequency power source is used as a sputtering power source, a DC sputtering method, and a pulsed DC sputtering method in which a bias is applied in a pulsed manner. An RF sputtering method is mainly used in the case where an insulating film is formed, and a DC sputtering method is mainly used in the case where a metal film is formed. RF sputtering is typically used in the methods of the disclosure in which the high-energy ions or particles are generated in response to a sputtering signal which varies with time. The sputtering signal can also include a signal which is substantially constant with time in addition to the time varying signal (i.e., bias sputtering). In some embodiments, the sputtering can be done in the presence of a magnetic field (i.e., magnetron sputtering). These methods of sputtering and others are well known to those skilled in the art.

Co-sputtering presents the advantage of being able to more accurately control the atomic fluxes for each individual metal. Additionally, the deposition rate is greatly increased when sputtering from metal targets, compared to a mixed pressed powder target, which means the oxygen incorporation would be reduced in films grown at low powers. Because of this, crystalline films can be synthesized with only 44-74 W RF power instead of the greater than 130 W needed for single target oxygen-free deposition. As with sputtering from a single target, decreasing the working pressure increases the deposition rate and thus decreases oxygen incorporation.

In fabricating a semiconductor device using GaN-based semiconductors, a c-plane substrate, i.e., a substrate of which the principal surface is a (0001) plane, is used as a substrate on which GaN semiconductor crystals will be grown. In a c plane, however, there is a slight shift in the c-axis direction between a Ga atom layer and a nitrogen atom layer, thus producing electrical polarization there. That is why the c plane is also called a “polar plane”.

ZnSiN₂ powder can be synthesized using high-pressure annealing, and thin films grown on sapphire, (100) silicon, or silicon carbide by metal-organic chemical vapor deposition (MOCVD). More extensive efforts were put into ZnGeN₂ fabrication leading to powders made by reaction in a furnace, single-crystal rods grown using the vapor-liquid-solid method, and thin films deposited on glass and silicon by radio frequency (RF) sputter deposition and on sapphire and silicon carbide using MOCVD.

The devices of the disclosure comprising the Zn-IV-N₂ materials find use in the fields of electronics, optoelectronics, molecular electronics, bioelectronics, the environment, tribology, photovoltaics and the biomedical field.

The following examples are intended to illustrate but not limit the disclosure. While they are typical of those that might be used, other procedures known to those skilled in the art may alternatively be used.

### EXAMPLES

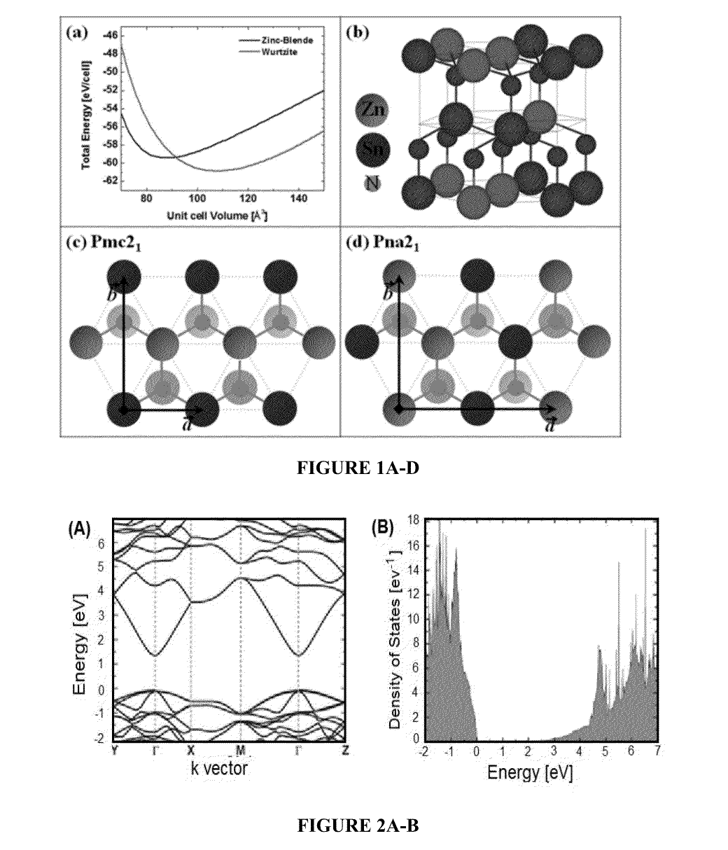

Initially the most stable structure of bulk ZnSnN₂ was explored by calculating the total energy per unit cell of possible crystal structures derived from those commonly found in nitride binary systems—zinc-blende and wurtzite—with selected Zn/Sn A-site orderings. FIG. 1a displays the calculated internal energy versus the unit cell volume, considering an ordered alloy with an 8-atom unit cell. In III-nitrides, the wurtzite P6₃mc structure is usually the most stable, and it is expected that wurtzite-derived structures to be most stable for ZnSnN₂. However, while this does turn out to be true, the energetic difference between the different wurtzite- and zinc-blende-derived were found to be small, suggesting that both phases, or indeed random Zn/Sn ordering, could coexist under certain growth conditions. In the wurtzite-derived structure, there are two high-symmetry ways to arrange the Zn and Sn atoms in the hexagonal c-plane (FIG. 1 c,d), corresponding to the orthorhombic Pmc2₁ and Pna2₁ space groups. Unfortunately, the two structures, which share many common super groups and differ only in the planar ordering of Zn and group-IV atoms, are difficult to experimentally differentiate. The calculated energy per nitrogen atom for both structures (Eₜₒₜ in Table 1) was also calculated and found them to be the same. The values of the corresponding lattice parameters at zero Kelvin, calculated using the hybrid HSE06 functional, are also listed in Table 1.

The calculated band structure and electronic density of states for orthorhombic ZnSnN₂ in the most stable space group, Pna2₁, are displayed in FIG. 2a,b. The hybrid functional calculations predict a zero Kelvin direct band gap of 1.42 eV. The recently reported theoretical band gap of 2.02 eV is not inconsistent with the prediction here, particularly because the quasi-particle self-consistent GW approach has been shown to overestimate band gaps of group-III nitrides by a few tenths of an electron volt. In wurtzitic III-nitrides, the breaking of cubic crystal symmetry between the ab-plane and the c-axis induces a splitting of the triply degenerate valence bands into the heavy hole, light hole, and spin-orbit sub-bands. In ZnSnN₂, the orthorhombic symmetry produced by the ordering of the mixed A-site, leads to a similar breaking of valence band degeneracy, as shown in the calculations (see, Table 1). The valence band splitting leads to three distinct exciton types at the optical absorption onset, but the small magnitude of the splitting will have a minimal impact on optoelectronic properties. Small in-plane and out-of-plane conduction band were calculated with effective masses of m_{c}*_{∥}=0.16 m₀ and m_{c}^{*}_{⊥}=0.13 m₀ (Table 1), which were expected to result in a high electron mobility and therefore good electrical conductivity for ZnSnN₂. Although the band-edge hole mobilities are more complicated due to the three distinct sub-bands with widely varying effective masses, in optically excited samples one would expect the hole mobility to be dominated by the collective light branches, with effective masses as low as 0.14 m₀.

The films of ZnSnN₂ were produced on sapphire(0001) and GaN(0001) template substrates by reactive RF magnetron sputtering from a single Zn_{0.75}Sn_{0.25} target or from Zn and Sn elemental targets at around 250° C. in an atmosphere of argon and nitrogen gases. The methods used to refine the deposition conditions are described below.

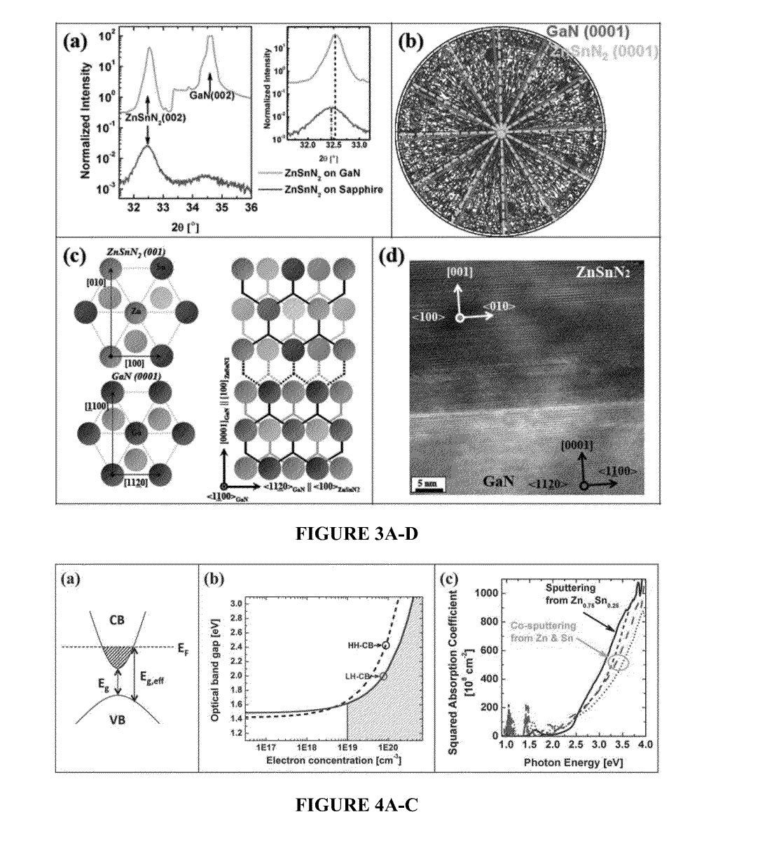

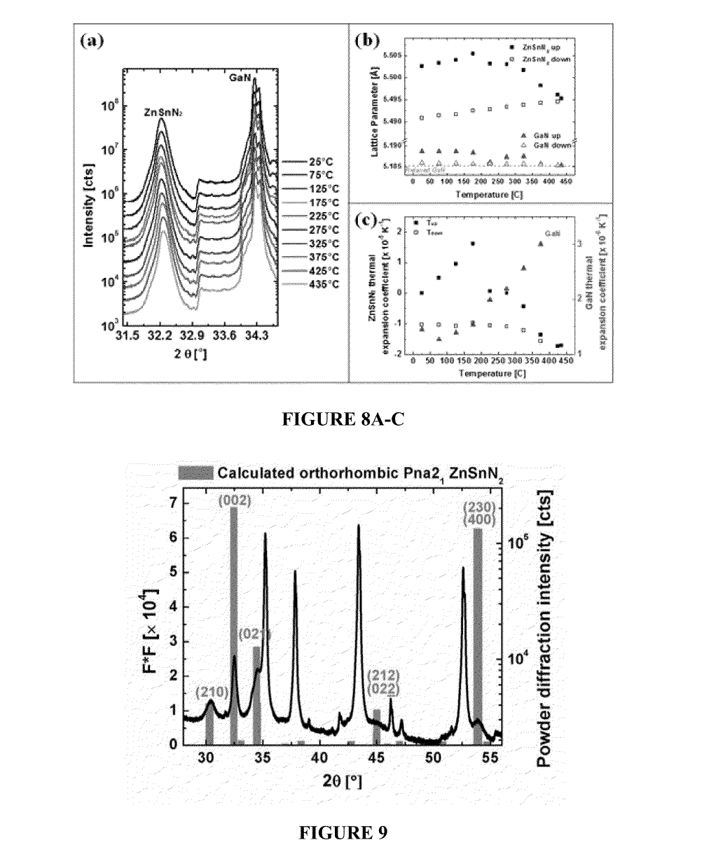

FIG. 3a compares the X-ray diffraction (XRD) measurements of ZnSnN₂ layers deposited under the same conditions on c-plane sapphire and GaN. Given the calculated zero Kelvin lattice parameters (Table 1) and assuming a certain thermal expansion of the layer (FIG. 8), the peak at 2θ˜32.3° was attributed to ZnSnN₂(002). The layers deposited on top of GaN templates not only exhibit a much sharper (002) peak, with a full width at half maximum reduced by a factor of two compared to layers deposited on sapphire, but also show a slight shift in the peak position towards larger 2θ angles. Both can be seen as consequences of the large difference in the lattice mismatch between the layer on GaN (˜6.5%) and the layer on sapphire (˜29%). The (002) orientation is further confirmed by a pole figure (FIG. 3b), in which the GaN template and the ZnSnN₂ layer have the same six-fold symmetry. From the symmetric 2θ-ω X-ray diffractograms alone, it could not be determined whether the structure is ordered according to Pmc2₁, Pna2₁, or a combination of both since they are expected to have very similar lattice parameters, as indicated in the ab initio calculations. Instead, ZnSnN₂ powder diffraction patterns were measured that match closely with Pna2₁ diffraction features (FIG. 9), indicating that this is the predominant arrangement. This is consistent with reports on synthesis of ZnGeN₂ and ZnSiN₂ materials where several groups have shown that they both exhibit the Pna2₁ structure.

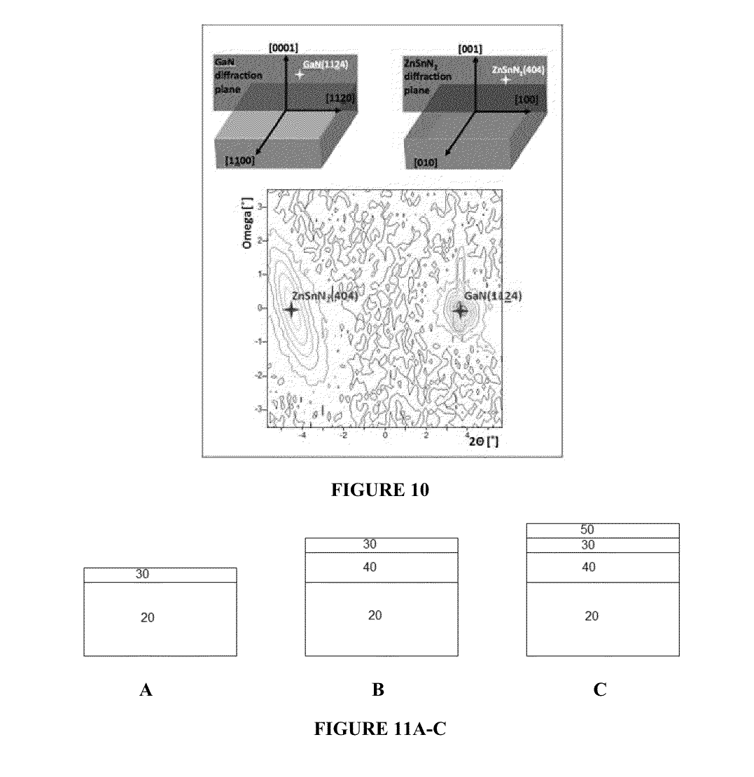

Heteroepitaxial growth of ZnSnN₂ is further confirmed by transmission electron microscopy analysis. FIG. 3d displays the micrograph of a co-sputtered ZnSnN₂ layer viewed along the <1120> azimuth of the GaN template. This image shows a sharp interface between the film and the substrate. It also provides the in-plane epitaxial relationship between the layer and GaN: <100>_{ZnSnN}_{₂}∥<1120>_{GaN} and <010>_{ZnSnN}_{₂}∥<1100>_{GaN}, confirmed by XRD measurements (FIG. 10). This configuration, illustrated in FIG. 3c, also allows for the smallest in-plane lattice mismatch between the GaN and the subsequent ZnSnN₂ layer: Δ_{<1120>}˜6.3% and Δ_{<1100>}˜6.6%.

Hall measurements performed on the layers reveal n-type material, with electron concentrations ranging from ˜2×10¹⁹ cm⁻³ to ˜9×10²⁰cm⁻³. This intrinsic doping is assumed to emanate from slight divergences in the stoichiometry. From the band structure calculations, a high electron mobility material is expected, however, mobilities of about 10 cm²V⁻¹s⁻¹ or lower were observed. The low mobility is believed to be due in part to the small grain size, which is typical for materials grown by sputtering. Another factor influencing the observed electron mobility could be a subtle band-filling effect, originating from the anharmonic nature of the conduction band at moderate non-zero crystal momenta. The band anharmonicity leads to a momentum-dependent effective mass, such that the cyclotron (transport) and band-edge effective masses differ appreciably (FIG. 2a). Refinements in structural and stoichiometric purity will increase the electron mobility.

For further study of the electronic structure, spectroscopic ellipsometry measurements were performed to reveal features in the joint density of states, particularly the optical band gap. For direct band gap semiconductors, the square of the absorption coefficient (α²) versus photon energy can be linearly extrapolated to the energy axis to estimate the value of the band gap. In FIG. 4c, a set of samples deposited under the optimized growth conditions, via sputtering and via co-sputtering were considered. All of the samples shown are nearly stoichiometric and are intrinsically n-doped with electron concentrations ranging from 4×10¹⁹ cm⁻³ to 5×10²⁰ cm⁻³. The data was linearly fit near the absorption edge to reveal a measured direct optical band gap for ZnSnN₂ between ˜2.1 eV and ˜2.3 eV. At first glance, the measured values of the band gap seem to be consistent with the recently reported theoretical band gap of 2.02 eV.^{[7]} However, the high carrier concentration in the sample combined with the low conduction band effective mass must incur a large Burstein-Moss effect in the apparent optical gap. As illustrated in FIG. 4a, free electrons will fill the bottom of the conduction band, pinning the Fermi level to energies above the conduction band edge, and consequently blocking low-energy optical excitations to yield a measured gap that is larger in energy than the underlying fundamental band gap of the material. As an example, the band gap initially reported for InN (1.9-2.1 eV), which is larger than the now-accepted gap of approximately 0.69 eV, has largely been attributed to this effect.^{[28, 29]} The calculated effective optical band gap depending on electron concentration (FIG. 4b), based on the calculated band structure (FIG. 2a), indicates that a gap of at least 1.8 eV should be expected for the electron concentrations measured. Ultimately, a precise experimental value of the fundamental band gap could not be assigned until the doping concentration in the material was reduced, but the combined theoretical and experimental study points to a fundamental gap in the red-green spectral region.

Thin films of stoichiometric ZnSnN₂ were synthesized that exhibit the predicted Pna2₁ wurtzite-derived orthorhombic crystal structure. The material has a measured optical absorption edge at around 2.1 eV to 2.3 eV, which is higher in energy than the theoretically predicted value of 1.4 eV. This difference is attributed to the Burstein-Moss effect, which is evidenced by large electron carrier concentrations according to Hall measurements. The findings of this study are believed to demonstrate the feasibility of fabricating stoichiometric, single-phase ZnSnN₂, a new earth-abundant small band gap semiconductor. These first optoelectronic measurements are promising for future applications, especially in photovoltaics and solid-state lighting.

Reactive RF Magnetron Sputter Deposition:

Thin films were synthesized in an AJA International sputtering chamber, with a background pressure in the high 10⁻⁸ Torr. The reactive RF plasma was created from a mixture of argon and nitrogen gases. The materials were deposited on c-sapphire and LUMILOG c-GaN template substrates from a Zn_{0.75}Sn_{0.25} target or from Zn and Sn elemental targets.

The approach for fabricating ZnSnN₂ layers was to use reactive RF magnetron sputter deposition. The atomic fluxes were controlled by the RF power applied to the metallic targets, and nitrogen was incorporated by sputtering in a reactive Ar/N₂ plasma. All targets were 2 inches in diameter and 0.250 inches thick. Films were deposited on c-plane sapphire and c-plane GaN templates at substrate temperatures ranging from room temperature up to 400° C.

Certain parameters were found to be useful to reach the proper conditions for stoichiometric and crystalline films. Such parameters include, but are not limited to: target composition (sputtering vs. co-sputtering), plasma power (species partial pressure) and deposition temperature. The gas ratio and working pressure are additional fine tuning knobs.

ZnₓSn₁₋ₓ pressed powder targets were acquired from ACI Alloys, Inc. and were 99.99% pure. Initially a Zn_{0.5}Sn_{0.5} target was used, which leads to stoichiometric ZnSnN₂ layers only if deposited below 150° C. However, low temperature deposition means low adatom surface mobility, thereby creating films with a poor crystalline quality. Increasing the deposition temperature tends to improve the layer quality, but the low sticking coefficient of Zn above 200° C. induces a shift in the stoichiometry towards zinc-deficient layers. Zinc desorption at high temperatures can be compensated by a zinc-rich source, which prompted the use of a Zn_{0.75}Sn_{0.25} target.

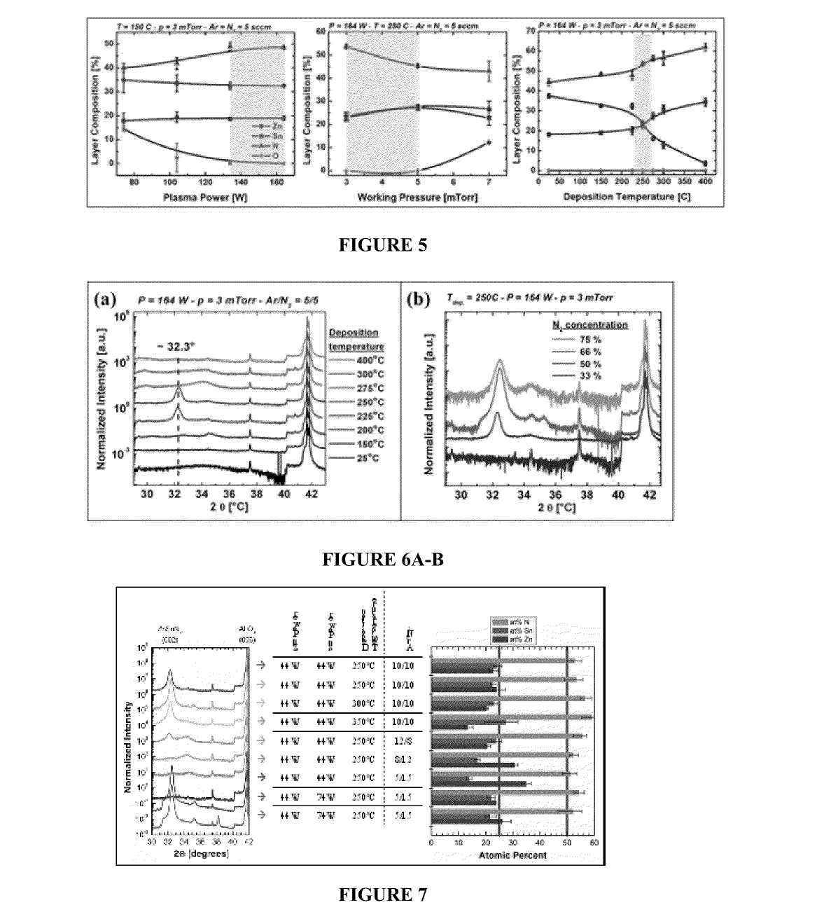

FIG. 5 records the composition of the layers as a function of the plasma power, the working pressure and the deposition temperature. A high concentration of oxygen is found in films deposited below 104 W, which were attributed to the low deposition rate (1-2 nm/min) at these low plasma powers. In this case, the partial pressure of the deposited species is in the same range as the partial pressure of oxygen in the chamber. When increasing the working pressure a decrease in the deposition rate (at 10 mTorr, films deposited for one hour are so thin that nearly no species can be detected by EDS) was observed, and a subsequent increase in the oxygen concentration in the layers. Hence, the combination of high plasma power and low working pressure gives the lowest oxygen concentration, most likely correlating with an increased deposition rate and decreased relative partial pressure of oxygen. The deposition temperatures were also varied at 164 W and 3 mTorr, which was a useful power/pressure combination to form a stable plasma. As illustrated in the right panel of FIG. 5, the layers are highly zinc-rich below 200° C., at which point a drastic drop in Zn concentration occurs that correlates with the increase in Sn and N atomic percentages. However, the growth window to avoid too much Zn desorption is rather small, as above 300° C. the layers become tin-rich. The layer stoichiometry was found to be strongly sensitive to the temperature, allowing for a small growth window of 250±25° C.

For all the deposition conditions tried, the crystalline quality of the layers was analyzed by X-ray diffraction. As an example, Supporting FIG. 6a presents the 2θ-ω X-ray diffractograms of layers deposited at different temperatures. The temperature of 250±25° C. not only leads to stoichiometric compounds but also allows for the fabrication of crystalline films, with a main peak at around 2θ=32.3°, attributed to ZnSnN₂(002) (explained further below). Further in FIG. 6b the effect of varying the Ar/N₂ ratio on the crystallinity is shown. While the effect on the stoichiometry of the alloy is negligible, a slight excess of nitrogen in the plasma increases the crystallinity of the layers such that 66% N₂ in the plasma leads to the best layer quality.

The other approach used for synthesis was co-sputtering from separate Zn and Sn elemental targets. These targets were acquired from the Kurt J. Lesker Company and are 99.99% and 99.999% pure for Zn and Sn respectively. Co-sputtering presents the advantage of being able to more accurately control the atomic fluxes for each individual metal. Additionally, the deposition rate is greatly increased when sputtering from metal targets, compared to a mixed pressed powder target, which means one can expect that the oxygen incorporation would be consequently reduced in films grown at low powers. Because of this, crystalline films can be synthesized with only 44-74 W RF power instead of the greater than 130 W needed for single target oxygen-free deposition. As with sputtering from a single target, decreasing the working pressure increases the deposition rate and thus decreases oxygen incorporation, so that it worked at 3 mTorr when co-sputtering.

FIG. 7 shows the X-ray diffractograms and corresponding film composition measurements for various co-sputtered samples deposited on c-sapphire using the conditions indicated in the table. Samples presented with close to ideal stoichiometry only show the ZnSnN₂(002) peak at 2θ=32.3°. However, as expected from the high vapor pressure of Zn metal, increasing the deposition temperature decreases the amount of Zn in the films; the layers tend to be optimized in terms of stoichiometry and crystallinity at 250±25° C. Of notice is a slight excess of N in all cases, thus reducing the atomic percentages of the metallic elements. Varying the N concentration in the plasma does not seem to have a significant effect on N incorporation in the films. However, it does have an effect on the metallic element incorporation, where increasing N₂ in the plasma results in a higher Zn/Sn ratio. In that case, tin-deficiency can be compensated by increasing the RF power on the Sn target. Once the proper Zn/Sn ratio is restored, the films show an increased crystallinity indicated by a sharper (002) peak. Hence, an ideal conditions to achieve stoichiometric samples with the good crystalline quality are 44 W Zn power, 74 W Sn power, 250° C., Ar/N₂ ratio of 5/15, and 3 mTorr working pressure.

X-Ray Diffraction (XRD):

The crystalline orientation of the layers has been studied by XRD measurements using a PANalytical X′Pert diffractometer with a beam concentrator prior to a 4-bounce Ge monochromator, using a Cu Kα source (λ=1.5406 Å), and a receiving slit of ½°.

Energy Dispersive X-Ray Spectroscopy (EDS):

Composition measurements were performed using a ZEISS 1550 VP field emission scanning electron microscope equipped with an Oxford INCA Energy 300 EDS System. The electrons were accelerated at a maximum of 7 kV, in order to avoid penetrating into the substrate and to have more precise quantitative information on the oxygen concentration of the layer itself.

Spectroscopic Ellipsometry:

Spectroscopic ellipsometry was performed on samples grown on c-sapphire at an incidence angle of 70° for 250 nm<λ<2300 nm with a Xe lamp visible light source and a Fourier-transform infrared spectrometer.

Computational Methods:

The structural and electronic properties were calculated using plane-wave density functional theory as implemented in the Vienna ab initio Simulation Package (VASP). The chosen exchange-correlation functional is the hybrid HSE06, which has been demonstrated to reproduce both ground-state properties and fundamental gaps with high accuracy. The core-valence partitioning is handled using the projector-augmented wave method, with datasets parameterized using the PBE-GGA functional. The wave functions were computed with periodic boundary conditions and expanded using a plane-wave basis with an energy cutoff of 800 eV. The tolerance for iterative improvement of the wave functions was 10⁻⁸ eV in both the total energy and electronic eigenvalues. The first Brillouin zone was discretely sampled using a 4×7×4 Monkhorst-Pack mesh. The atomic structure was relaxed using a quasi-Newton algorithm until all force components were less than n 10⁻⁴ eV/Ang.

To date, there is no report on the synthesis of orthorhombic ZnSnN₂. Therefore, its room temperature lattice parameters have not been experimentally measured, but only theoretically calculated at zero Kelvin using various methods. One goal here is to extrapolate the HSE06 zero Kelvin calculations to 300 K in order to verify that the expected wurtzite-derived structure was synthesized.

Temperature-dependent X-ray diffraction experiments were performed in air to measure the thermal expansion of the film. Starting around 475° C., the film starts to decompose and is then entirely sublimated at 550° C. A 2θ-ω diffraction scans were recorded every 10° C. to 25° C., ramping the temperature up from room temperature to 450° C. and back down to room temperature. One can clearly observe the shift in the 2θ position of the ZnSnN₂(002) peak when varying the temperature (FIG. 8a). In FIG. 8b, the evolution of the out-of-plane lattice parameters, c, were plotted for both GaN and ZnSnN₂. The value of the c parameter is calculated assuming a relaxed GaN template with c=5.185 Å at room temperature. It is interesting to note that one can differentiate two phases in the thermal evolution; first the ZnSnN₂ layer shows a linear increase of its lattice dimensions, following the GaN behavior, then a drastic change occurs at around 200° C. when c of ZnSnN₂ starts to decrease. This drop could be interpreted as a temperature-enhanced phase change of the crystal. On the other hand, it could also be seen as evidence of lattice relaxation, since the layer grows in compression on the GaN template. From this set of experiments, the thermal expansion coefficient along the c axis, α_{c}, was calculated. The data was verified to be consistent with values commonly found for GaN^{[S1]}. For ZnSnN₂, an expansion coefficient was determined that is relative to the strain state of the as-grown layer (FIG. 8c). This gives us a good estimation of the range of thermal expansion values compared to GaN, and it is important to notice that the expansion is one order of magnitude lower for ZnSnN₂ than for GaN.

Additionally, a thick ZnSnN₂ layer (˜1.5 μm) was fabricated onto a thin c-sapphire substrate (100 μm) in order to obtain a higher volumetric ratio of ZnSnN₂ to Al₂O₃ than for standard epilayers. The sample was ground using a mortar and pestle so that a detailed powder diffraction pattern could be measured. The powder 20-w scan is presented in FIG. 9. In this diagram, the sharp peaks are attributed to diffraction from sapphire planes, while the broader ones are from ZnSnN₂. The values of the F*F factors, for both Pmc2₁ and Pna2₁ crystallographic configurations, were calculated assuming certain thermal expansion coefficients for the zero Kelvin lattice parameters recorded in Table 1.

TABLE 1
Zero Kelvin equilibrium lattice parameters for
the wurtzite-derived Pna2₁ and Pmc2₁ orthorhombic
structures, and electronic properties for the Pna2₁
structure, calculated using the hybrid HSE06 functional.

| | | | Electronic Properties | | | |
|---|---|---|---|---|---|---|
| | Lattice | | | Δε_{VBM} | | |
| Structure | Parameters | | Band | (eV) | m*_{\|\|} | m*_{⊥} |
| Pna2₁ | a₀ (Å) | 6.721 | CB | 1.42 | 0.16 | 0.13 |
| | b₀ (Å) | 5.842 | VB₁ | 0.00 | 2.15 | 0.14 |
| | c₀ (Å) | 5.459 | VB₂ | −0.04 | 2.21 | 1.74 |
| | Eₜₒₜ | −10.89 | VB₃ | −0.05 | 0.15 | 1.19 |
| | (eV/N) | | | | | |
| Pmc2₁ | a₀ (Å) | 3.388 | | | | |
| | b₀ (Å) | 5.771 | | | | |
| | c₀ (Å) | 5.427 | | | | |
| | Eₜₒₜ | −10.89 | | | | |
| | (eV/N) | | | | | |

The calculated F*F for the Pna2₁ structure is superimposed on the diffraction pattern in FIG. 9. The 300 K lattice parameters, assuming the layer is strained on GaN and considering an out-of-plane thermal expansion coefficient was calculated to be α_{c}=2.7×10⁻⁵K⁻¹, in the range of the values measured in FIG. 8c. Because of the strong asymmetry in the structure, it is likely that the in-plane thermal expansion would not follow the same behavior, as is the case for III-nitrides. However, the structure factors of the Pna2₁ crystallographic phase were found to match closely with the ZnSnN₂ powder diffraction peaks if in-plane coefficients of αₐ=3.5×10⁻⁵ K⁻¹ and α_{b}=2.5×10⁻⁵ K⁻¹ were used. This is an indication that ZnSnN₂ in fact crystallizes into the Pna2₁ structure as predicted.

Epitaxial Relationship Between ZnSnN₂ and GaN.

For heteroepitaxy, it is desirable to determine the epitaxial relationship between the layer and its underlying substrate. For that purpose, X-ray diffraction and transmission electron microscopy (TEM) were used as two complementary techniques. As shown in FIG. 3b, pole figures confirmed that ZnSnN₂ has the same (001) orientation as the GaN, which means that the c-axes of both structures are parallel. Additionally, the in-plane orientation of the layer with respect to the GaN can be assessed using asymmetric reciprocal space maps. Asymmetric reflections are those coming from planes that form a non-zero angle with the growth plane, so that their normal vector has components both along the growth axis and within the growth plane. For c-oriented layers, the diffraction plane is either formed by [0001] and [1120] axes or by [0001] and [1100] axes (FIG. 10). Knowing the out-of-plane axis, the in-plane axis can be determined from the presence of one reflection in the diffraction plane that is composed of both the in-plane and out-of-plane vectors.

For ZnSnN₂, the (404) reflection was found to be close to the (1124) reflection from GaN. With {404}=4×{100}+4×{001} and {1124}=1×{1120}+4×{0001}, it was concluded that the in-plane epitaxial relationship: <100>_{ZnSnN}_{₂}∥<1120>_{GaN} and consequently, <010>_{ZnSnN}_{₂}∥<1100>_{GaN}. This epitaxial arrangement was verified with high-resolution cross-sectional TEM, as illustrated in FIG. 3d. Note that the direction of the unit vectors cannot be determined by XRD measurements.

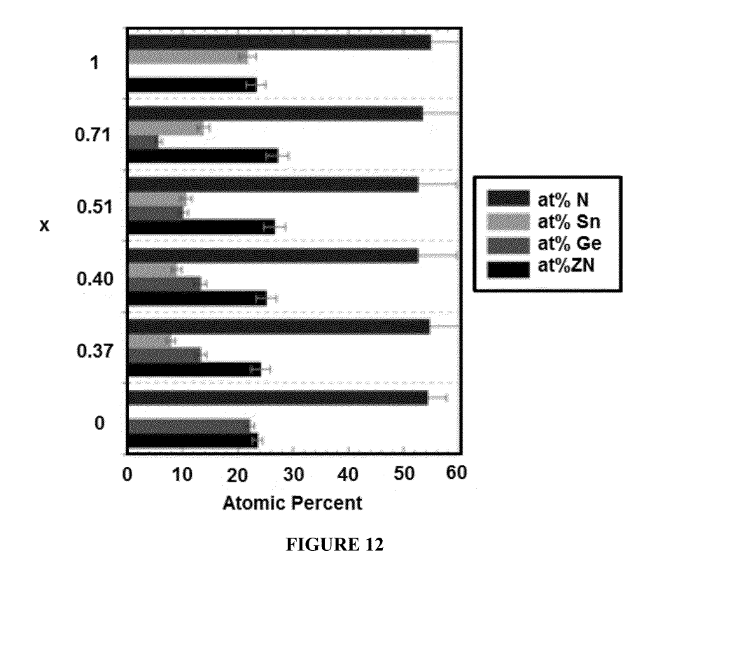

ZnSnₓGe₁₋ₓN₂ thin films were deposited on c-sapphire by reactive RF co-sputtering from metal targets in an Ar/N2 plasma. The chamber pressure was kept at 3 mTorr during deposition with 75% nitrogen in the plasma, and the substrate temperature was held at around 270° C. For x=0 or 1, films were deposited by co-sputtering from zinc and germanium or tin elemental targets with RF powers of 44W on zinc and 44W to 104W on germanium or tin. For 0<x<1, the targets used were Zn_{0.75}Sn_{0.25} and Ge. The combined target is zinc-rich because the high vapor pressure of zinc limits its incorporation during deposition. For the data presented here, the RF power on the Zn_{0.75}Sn_{0.25} target was 134W and the power applied to Ge varied from 44W to 134W to create a set of samples with ranging composition. From previous studies, it was determined that the combined target requires higher power than the elemental targets to increase the deposition rate and reduce oxygen incorporation. Composition measurements were made using energy dispersive X-ray spectroscopy and showed that all samples had close to 25 at % zinc and 50 at % nitrogen (see FIG. 12). The value of x was calculated by taking the ratio of atomic percent tin to the total atomic percent of group IV elements.

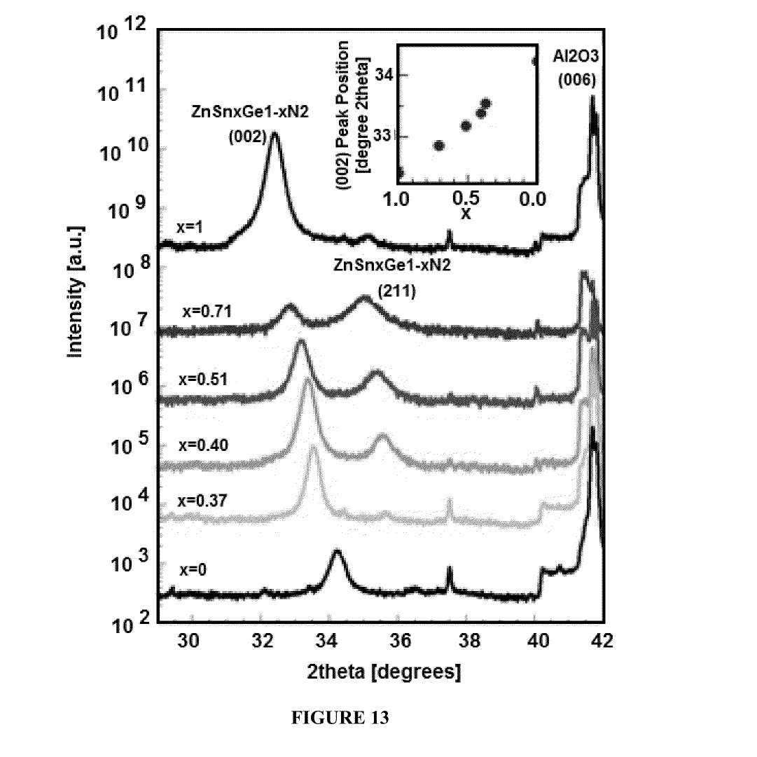

X-ray diffraction measurements were performed to determine the crystallinity and orientation of the films. The ZnSnN₂ and ZnGeN₂ films both have a main (002) peak where the peak position matches well with the calculated lattice parameter for each material. For films with 0<x<1, there are two prominent peaks corresponding to the (002) and (211) orientations (see FIG. 13). The 2θ position of the (002) peak linearly increases with increasing germanium content between the ZnSnN₂ and ZnGeN₂ (002) peak positions (see, FIG. 13, inset). Because the peak is continuously shifting with changing composition, it's believed the material is in fact alloying, with no observable phase separation according to the X-ray diffraction analysis. This is unlike what occurs in InₓGa₁₋ₓN growth because the difference in lattice parameter between ZnSnN₂ and ZnGeN₂ is about half as much as the difference between InN and GaN. Therefore, the material is able to accommodate a larger range of compositions without straining the lattice to a point where phase separation is favorable.

Spectroscopic ellipsometry was used to measure the absorption coefficient of the films, and the linear extrapolation of the squared absorption coefficient versus energy gives the optical band gap of the material. The optical absorption edge of above 2.0 eV for ZnSnN2 is much larger than the calculated value of 1.4 eV due to a high electron carrier concentration (up to 10²¹ cm⁻²) contributing to Burstein-Moss effects. The small conduction band effective mass of ZnSnN₂ is what allows the absorption energy to increase by such a large amount with the high carrier concentration. For ZnGeN₂, an absorption edge of about 3.1 eV was measured, which is slightly higher than the calculated value of about 2.9 eV but less than the experimentally measured value of 3.4 eV reported by Du et al. (J. Cryst. Growth 310, 2008, pp. 1057-1061). The larger conduction band effective mass of ZnGeN₂ may be limiting the increase in absorption energy if the material is largely n-doped.

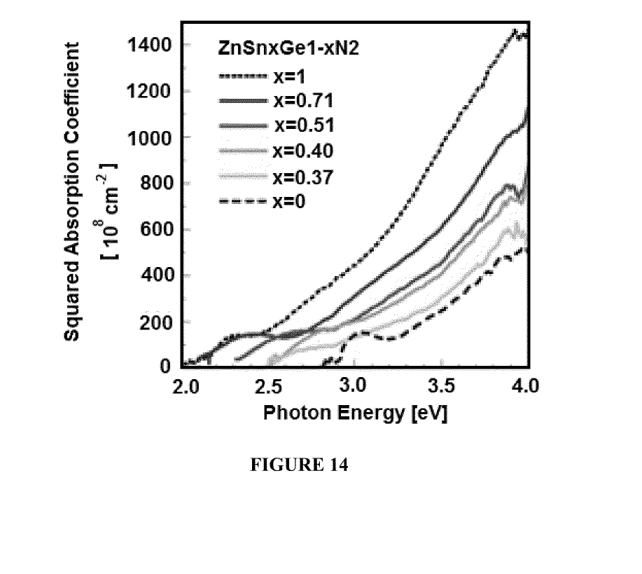

For the ZnSnₓGe₁₋ₓN₂ samples with 0<x<1, the plots for the squared absorption coefficient versus photon energy fall between the plots for x=0 and x=1 (see FIG. 14). The absorption edge increases with increasing germanium content, but the trend does not appear to be linear. It is unclear if the non-linearity is characteristic of this material system or if it results from a diminishing Burstein-Moss effect as the germanium content is increased. Nevertheless, these results are promising because they show that the band gap of ZnSnₓGe₁₋ₓN₂ alloys can be varied over a wide range as a function of the composition.

The results presented here indicate that ZnSnₓGe₁₋ₓN₂ alloys are promising alternative material to InₓGa₁₋ₓN for use as photovoltaic absorber layers with a tunable band gap. Although the range of possible band gaps is smaller than for InₓGa₁₋ₓN, the ZnSnₓGe₁₋ₓN₂ alloys still span a large part of the solar spectrum and will be able to access their entire range because they do not suffer from phase separation as the composition is changed. The range of accessible band gaps could also be extended into the ultraviolet with ZnGexSi1-xN2 alloys. If the device properties of ZnSnₓGe₁₋ₓN₂ are comparable to those of InₓGa₁₋ₓN, it may be possible to achieve large-scale, inexpensive, and efficient solar energy conversion in the near future.

The disclosure provides a number of Zn-IV-N₂ materials, with IV=Sn, Ge, or Si, that are earth-abundant and have predicted properties similar to the III-N system for use in photovoltaics. In one aspect, ZnSnₓGe₁₋ₓN₂ was identified as a tunable band gap absorber material. The disclosure demonstrates thin film growth of ZnSnₓGe₁₋ₓN₂ alloys by reactive RF co-sputtering from metal targets in nitrogen-rich plasma, where x is varied by changing the RF power applied to the targets. The results show that the (002) peak position from X-ray diffraction linearly increases with increasing germanium content over a wide range of compositions, indicating that phase separation is not occurring. Additionally, the measured optical absorption edge also increases with increasing germanium, indicating that the band gap is tunable over the same composition range. Thus, ZnSnₓGe₁₋ₓ N₂ is an earth-abundant alternative to InₓGa₁₋ₓN alloys for low-cost photovoltaics.

A number of embodiments of the invention have been described. Nevertheless, it will be understood that various modifications may be made without departing from the spirit and scope of the invention. Accordingly, other embodiments are within the scope of the following claims.

What is claimed is:

1. A semiconductive device, comprising:
a substrate layer; and
at least one absorber layer comprising Zn-IV-N₂ or Zn-IV₁-IV₂-N₂, where IV=Sn, Ge, or Si deposited on the substrate layer and wherein IV₁ and IV₂ are not the same.

2. The semiconductive device of claim 1, wherein the substrate is selected from the group consisting of silicon, silicon carbide, sapphire, aluminum nitride and Ga—N.

3. The semiconductive device of claim 1, wherein the substrate is selected from the group consisting of silicon, silicon carbide, sapphire and aluminum nitride and wherein a layer of Ga—N is layered on the substrate.

4. The semiconductive device of claim 3, further comprising a nucleation layer between the substrate and the Ga—N buffer layer.

5. The semiconductive device of claim 1, wherein the absorber layer comprises ZnSnN₂.

6. The semiconductive device of claim 5, further comprising a window layer of ZnSiN₂.

7. The semiconductive device of claim 1, wherein the absorber layer comprises a ZnSnN₂/ZnGeN₂ type II heterojunction.

8. The semiconductive device of claim 1, wherein the absorber layer comprises gradual band gap absorber layers made of ZnₓSn_{y}Ge_{1-x-y}N₂.

9. The semiconductive device of claim 5, wherein the ZnSnN₂ layer exhibit the wurtzite-derived Pna2₁ orthorhombic structure.

10. The semiconductive device of claim 9 having one or more of the following characteristics selected from the group consisting of:
(a) a band gap of about 1.4 eV at zero Kelvin;
(b) an optical band gap of about 2.1 eV; and
(c) electron concentrations of about 10²¹ cm⁻².

11. A method of making a semiconductive ZnSnN₂ thin film, comprising RF-sputtering (i) ZnₓSn₁₋ₓ, or (ii) Zn and Sn in an Ar/N₂ plasma on a substrate.

12. A method of making ZnSnₓGe₁₋ₓN₂ alloy thin films with 0<x<1 by reactive RF sputtering, chemical vapor deposition, or molecular beam epitaxy on a substrate.

13. The method of claim 11 or 12, wherein the substrate is selected from the group consisting of silicon, silicon carbide, sapphire, aluminum nitride and Ga—N.

14. The method of claim 11 or 12, wherein the substrate is selected from the group consisting of silicon, silicon carbide, sapphire and aluminum nitride and wherein a layer of Ga—N is layered on the substrate.

15. The method of claim 11 or 12, further comprising the step of removing the substrate.

16. A semiconductive device made by the method of claim 11 or 12.
